(19) United States
(12) Patent Application Publication
(10) Pub. No.: US 2005/0160335 A1
(43) Pub. Date: Jul. 21, 2005

(54) System and method for monitoring state information in a network

(76) Inventor: Alec H. Peterson, Evergreen, CO (US)

Correspondence Address: Steven P. Arnheim;Shaw Pittman LLP, 1650 Tysons Blvd., McLean, VA, 22102, US

(21) Appl. No.: 11/032,148

(22) Filed: Jan. 11, 2005

Related U.S. Application Data
(63) Continuation-in-part of application No. 10/194,071, filed on Jul. 15, 2002.
(60) Provisional application No. 60/535,817, filed on Jan. 13, 2004.

(51) Int. Cl. H04L 1/00; H04J 1/16; H04J 3/14; G06F 11/00; G08C 15/00; H04L 12/26; G01R 31/08; G01R 31/28

(52) U.S. Cl. 714/724

(57) ABSTRACT

Agents are instructed execute network tests during monitoring intervals. Results of the tests are stored. After expiration of a dampening window period the results are retrieved and evaluated. The evaluation is used to update an error state stored in a data structure in a database as required. Notification of detected errors is provided if certain notification dampening criteria are satisfied.

This application is a continuation-in-part of U.S. patent application Ser. No. 10/194,071, filed Jul. 15, 2002. This application also claims the benefit of U.S. Provisional Application No. 60/535,817, filed Jan.13, 2004, which is herein incorporated by reference in its entirety.

### BACKGROUND

1. Field of the Invention

The present invention relates generally to monitoring operation of computer networks. More particularly, the present invention relates to monitoring and maintaining and propagating an error state in a computer network.

2. Background of the Invention

Computer networks have become central in virtually all aspects of modern living. Medical, legal, financial and entertainment institutions rely on the proper functioning of such networks to offer their services to their clients. However, as is well-known, computer networks are prone to failures including equipment and communication failures as well as security breaches. Consequently, computer networks must be monitored to ensure their proper functioning.

One example of such monitoring is monitoring of websites on the Internet. This monitoring can be performed repeatedly from numerous access sites, for example, on a periodic basis such as every fifteen minutes. A critical issue associated with repeated periodic monitoring of websites is the vast amount of data that is created during the monitoring process. Although such data may be useful for performing statistical tests such as trending analysis, it is generally not useful in the context of error reporting.

One source of this large amount of repetitious data is repetitious error reporting. Such repetitious error reporting can cause a significant drain on network resources leading to increased costs and higher likelihood of network failure. A common cause of repetitious error reporting is that the same error or errors are reported from each of the multiple sites that monitor the website.

Some conventional systems attempt to avoid some of this repetition by aggregating error messages. In these conventional systems, errors are stored until a particular number or percentage of agents detecting the error exceeds an error threshold. If the threshold is exceeded, notification of which agents detected the problem is provided. These systems provide an indication of when the error condition has been corrected by providing a notification of when the error threshold is no longer exceeded. However, such systems do not provide detailed information related to the error that gave rise to the notification. Moreover, such systems do not provide an indication of the change in error state. That is, if in fixing the problem that gave rise to the notification, another error is introduced, no notification of the change in the error conditions is provided. Rather, notification of the later error is provided only after the error threshold has once again been exceeded.

### SUMMARY OF THE INVENTION

The present invention provides a system and method for maintaining a state on various error conditions associated with network testing. The present invention evaluates monitoring results and maintains an error states based on them so that once an error condition is detected it is stored as an error state. The present invention then provides notification on that state on the basis of a certain set of dampening parameters.

Multiple error states can also be maintained for multiple testing sites. For example, one error may be detected from a particular monitoring point, and another error may be detected from that or another monitoring point. Multiple error conditions are represented by error states that include indications of the multiple detected errors. A different state is entered for each different set of errors that is detected. However, if the error or errors are repeating, only one notification of each particular error is provided.

In operation, the system captures a user- or system-generated baseline state for a particular test. Multiple baseline states can be captured, each corresponding to a different test. During system operation, testing is performed in the network. Any errors are used by the system to update the current error state or states for the corresponding test. Differences from the baseline state, as indicated by the error states, are reported. Baselines can be amended or reset during system operation.

Preferably, there are two test categories, security tests and performance tests. Security tests are used to find and report potential security breaches in a network. The baseline state used for security tests is preferably a stored state that is obtained at startup. An error is indicated in a security test when the test results in a state that differs from the baseline state. Performance tests are used to determine how well a network is performing its tasks. The baseline state used for performance tests is preferably a no error state. That is, the network is operating as designed. An error is indicated in a performance test when a test results in abnormal network operation.

In one embodiment, the present invention is a system for maintaining an error state corresponding to agent testing of a computer network. One or more agents in the system execute a test of the computer network. An error data structure is associated with each agent for storing an error state associated with the test performed by the agent associated with the error data structure. An initiator in the system initiates the test. An evaluation engine evaluates result messages returned by the one or more agents after the one or more agents execute the test in the context of the error data structure associated with each agent. The evaluation engine waits until expiration of a dampening window prior to evaluating the result messages, and then updates the error data structure associated with each agent in accordance with the result messages returned by the one or more agents. The error data structures are stored in a database. A notification system notifies a user of detected errors.

In another embodiment, the present invention is a method for maintaining and reporting an error state corresponding to agent testing of a computer network. The method includes the step of conducting a test of the computer network. Result messages are received after conducting the test. The result messages are stored in a database. The method then continues with the step of determining if a dampening window has expired. If the dampening window has expired, the method continues with the steps of loading the stored result from the database and evaluating the result. The method then continues with the step of determining if a current error state has changed into a new error state. If the current error state has changed, a user is notified of the new error state.

### BRIEF DESCRIPTION OF THE DRAWINGS

FIG. 1 is a schematic diagram of a system for maintaining and reporting an error state of a computer network during monitoring of the computer network according to an embodiment of the present invention.

FIG. 2 is a flow chart for maintaining and reporting an error state of a computer network after receiving a result message from an agent during monitoring of the computer network according to an embodiment of the present invention.

FIG. 3A illustrates an exemplary graphical user interface for allowing a user to provide inputs for a TLD name server test according to an embodiment of the present invention.

FIG. 3B illustrates an exemplary graphical user interface for notifying a user of the results of a TLD name server test according to an embodiment of the present invention.

FIG. 4 is a flow chart for performing a security test in accordance with an embodiment of the present invention.

FIG. 5 is a flow chart for performing a performance test in accordance with an embodiment of the present invention.

### DETAILED DESCRIPTION OF THE INVENTION

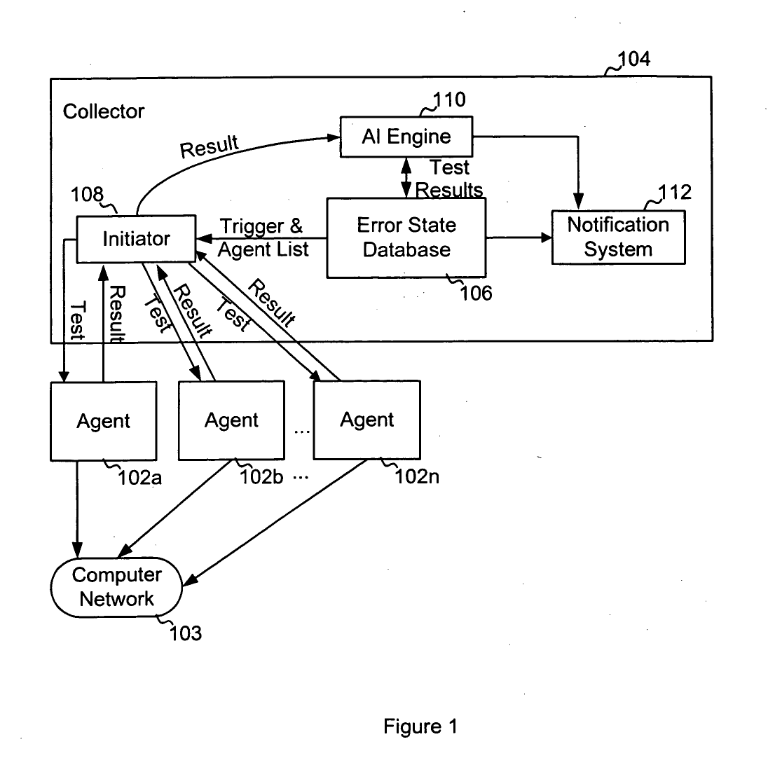

FIG. 1 is a schematic diagram of a system for maintaining an error state according to an embodiment of the present invention. As used herein, the term “state” refers to a set of detected conditions. Thus, an error state is a set of detected error conditions.

In the embodiment of the present invention illustrated in FIG. 1, N agents 102a, 102b, . . . 102n monitor a computer network 103 by executing tests on network 103. N can be any positive integer. As described in more detail below, the tests include network security tests, network communication tests and network equipment tests. Agents 102a, 102b, . . . 102n communicate with a collector 104 to execute tests for monitoring network 103, return results of the tests, maintain error states describing the error state of network 103, and provide notification to users. Collector 104 comprises an error state database 106, an initiator 108, an AI engine 110 and a notification system 112.

Error state database 106 stores an error state for each test performed by each agent in the system. An exemplary error state database 106 is an Oracle database. Preferably, error states are stored in a data structure that has fields established for storing error conditions of interest. Preferably, there is an error data structure established for each error condition that is to be tracked using the present invention. Moreover, preferably there is a unique error state maintained for each agent (monitoring site) that performs a test. Consequently, an error state is maintained for each agent for each test that the agent performs. Thus each error state data structure can be identified by a two-dimensional tuple of (test ID, agent ID)

For example, if two agents perform a particular test, but obtain different results, the different results are maintained in separate data structures. Preferably, results obtained by agents are stored in separate data structures even when the results are the same. Maintaining this information in a separate manner may provide more specific information regarding error conditions in a network. For example, where the agents are implemented at different ISPs, different errors allows a trouble shooter to determine if one ISP is affected by an error, whereas another is not.

In addition, error states can be maintained for multiple objects by multiple agents. For example, multiple objects in a web page (e.g., embedded images, text, banners, etc.) can be monitored by assigning a separate error state data structure to each object in the web page. In that case, each agent that monitors one or more of the objects in the web page has a separate error state data structure corresponding to the particular object that the agent is monitoring. In this case, the object can be referenced by a three-dimensional tuple of (test ID, agent ID, object ID).

Other tests can be identified by large-dimensioned tuples. For example, a test of a series of URL's can be identified by a four dimensional tuple of (test ID, agent ID, URL ID, object ID). In this case, the URL ID is associated with the particular URL being tested and the object ID is associated with the object in the URL being tested.

An exemplary data structure for storing error state information according to an embodiment of the present invention is provided by the data structure “general_error_state_bitmap” as follows:

```
struct general_error_state_bitmap {
    unsigned int err_exist:1;
    unsigned int err_new:1;
    unsigned int err_repeat:1;
    unsigned int err_corrected:1;
    unsigned int err_reported:1;
    unsigned int err_prev_corrected:1;
    unsigned int err_reserved:2;
};
```

As shown, preferably, the error state bitmap is an eight_bit data structure corresponding to eight error condition fields. The err_exist field indicates whether the error existed during a current evaluation window. The err_exist field is set when evaluation of result messages returned by agents indicates that an error exists during the evaluation window. The err_new field indicates whether the particular error was new during the evaluation window (i.e., the error did not appear in the previous evaluation window). The err_new field is set when evaluation of result messages returned by agents indicates that the error is a new error during the evaluation window. The err_repeat field indicates whether the error occurred more than once within a particular evaluation window. The err_exist field is set when evaluation of result messages returned by agents indicates that an error occurs more than once during the evaluation window. The err_corrected field indicates that there was at least one instance within the evaluation window where the error was not present. The err_corrected field is set when evaluation of result messages returned by agents indicates that the error was present but is not present after at least one test in an evaluation window. The err_reported field can be used to indicate whether the error was reported. The err_reported field is set when the error has already been reported to the notification system. The err_prev_corrected field indicates whether an error that existed in the previous evaluation window is corrected in this evaluation window. The err_prev_corrected field is set when evaluation of result messages returned by agents indicates that an error that existed in a previous window does not exist in the current evaluation window. The err_reserved field are reserved fields for future use. An advantage of adding the reserved bits is to have the data structure align on an eight-bit boundary.

This data structure can be used even in cases where errors are fixed but recur in a single evaluation window. For example, if the error did not occur in the previous evaluation window, the err_exist, err_new, err_repeat and err_corrected fields are set. If the error did occur in the previous window, the err_exist, err_repeat, err_corrected and err_prev_corrected fields are set.

Initially, each error state is set to indicate no errors in the network. If an error is detected by an agent, a new error state is entered. The new error state includes an indication of the detected error. The new error state is maintained as long as the error persists. If all errors in the network are cleared, each error state is preferably purged to avoid any lingering problems. Purging means that the error state is returned to the initial no error condition.

In addition to storing error states for each test performed by each agent, error state database 106 initiates execution of each test to be executed. To initiate a test, database 106 provides a trigger and a test agent list to an initiator 108. The agent list can include all agents or only a portion of the agents to perform the test. Preferably, the trigger is provided at the expiration of a monitoring interval for a particular test. The monitoring interval is the time interval that must elapse between each iteration of a particular test. A separate monitoring interval can be maintained for each different test that is performed by the system. In addition, separate monitoring intervals can be maintained for each agent. Tests can be initiated immediately after expiration of their corresponding monitoring intervals or after a delay after expiration of their corresponding monitoring windows. Preferably, evaluation of test result messages returned by agents is performed after expiration of an evaluation interval (described below).

In one embodiment of the present invention, test scheduling is performed using a modified UNIX scheduler. The UNIX scheduler is modified to overcome the operation of the UNIX scheduler to always perform some action. In the present invention, the UNIX scheduler is made to operate under the assumption that actions are to take place only at certain times. This modification prevents the UNIX scheduler from operating in its conventional manner by trying to perform actions whenever there are free cycles. Modification of the UNIX scheduler in this manner is necessary to avoid server overloading issues.

Initiator 108 receives the test request from error state database 106. In response to the request, initiator 108 provides a command to each agent in the agent list to perform the requested test. After an agent completes a test, the agent returns a test result to initiator 108. Initiator 108 passes the returned test result to AI engine 110 for evaluation.

AI engine 110 evaluates the test results in light of the current error state for that test for that agent. Preferably, AI engine 110 evaluates error states after expiration of an evaluation interval or window. The evaluation window or interval is also called a dampening window. The dampening window is a period of time that allows aggregation of data collected by each agent executing tests during a monitoring interval. Preferably, the dampening window is set long enough so that it is likely that all agents that execute a test will have performed at least one iteration of the test and received results for the test that it is responsible for performing. For example, the dampening window can be 1.5 times the monitoring window. For example, if the monitoring window is 15 minutes, the dampening window is 22 minutes 30 seconds.

A new dampening window begins when the previous dampening window is evaluated. The dampening window expires when a result from a test is received by the agent after a period of 1.5 times (or some other user-selected or system-generated time period) the monitoring interval has elapsed. In another embodiment of the present invention, the dampening window expires after a period of 1.5 times (or some other user-selected or system-generated time period) the monitoring window has elapsed. A timer such as a system clock or counter can be used to track the duration of the current dampening window.

The dampening window provides several benefits over returning results immediately upon expiration of a test's monitoring interval. As mentioned above, use of the dampening window provides time for each agent to perform its test or tests and send the results to AI engine 110 for processing. Thus, the dampening window allows for the agents to test at random times within a test's monitoring window. The random nature of test timing within a monitoring window means that in general not all test results are available at the expiration of the monitoring interval. Because all of the results from the agents performing testing are available, the results can be returned in a single notification message (e.g., a single email message) to notify users of the error state of the network. There would be no additional notifications required for agents not completing testing until after the monitoring interval had expired. In this manner, the dampening window reduces the volume of notification messages that would otherwise be sent.

Error states are updated at the end of the dampening window. Thus, one or more iterations of test and received results is performed for every agent in the system. Error states are updated based on the existing error states and the results of the tests. The various error states are described above.

To evaluate the results, AI engine 110 loads any result messages that were returned and stored during the last expired dampening window period. The results are then evaluated. To avoid numerous inefficient database queries that would otherwise be required to access the stored results, the stored results are preferably stored on a local random access memory (RAM) cache for evaluation.

After the results are evaluated, AI engine 110 updates any error states in database 106 that have changed. In addition, AI engine 110 provides a message to notification system 112 of any states that indicate the presence of one or more error conditions and/or one or more error corrections.

Notification system 112 determines whether to notify a user of the error(s) or error correction(s) based on a notification dampening window. The notification dampening window is established by notification dampening criteria. These criteria must be satisfied (i.e., the notification window must expire) prior to providing notification. There are preferably two kinds of notification dampening that can be performed. A first kind of notification dampening is error-persistence notification dampening. Error-persistence notification dampening measures the duration of a particular error. If the error persists for longer than a pre-determined amount of time, the error is reported. The pre-determined amount of time is a threshold that can be user-provided or system-provided. The pre-determined amount of time can be in terms of a number of dampening window periods. Thus, the notification system of the present invention does not notify a user of the error or error correction until the error has persisted for longer than the pre-determined amount of time.

To provide error-persistence notification dampening, the system tracks the time an error started, and how long it persists. Tracking the beginning time of the error and its persistence provides another benefit of the present invention. For example, this tracking information can be used to create an error instance tracking log that can be provided to users so they can monitor error instance data.

A second type of notification dampening is agent dampening. With agent dampening, notification of error state is not provided to a user unless a pre-determined number of agents detects the error. The pre-determined number of agents is a threshold that can be user-provided or system-provided.

The two types of notification can be used together. That is, by setting the thresholds for error persistence and agent dampening, an error is not reported unless the error persists for the persistence threshold duration as seen by a minimum number of agents.

In addition, setting the error-persistence threshold for a particular error to zero means that the system does not wait for the error to persist prior to providing notification of the error. Thus, only the agent number threshold is meaningful. Likewise, setting the agent number threshold for a particular error to zero means that the system does not wait for the threshold number of agents to see the error prior to providing notification. Thus, only the time threshold is meaningful. Setting both thresholds to zero essentially eliminates the notification dampening window. That is, notification proceeds uninhibited by the error persistence or agent number thresholds. Notification can also be turned off.

In another embodiment of the present invention, notification can be performed in the alternative. That is, notification dampening can be defined so that notification is performed if, for example, either the time threshold or the agent number threshold were exceeded.

Preferably, the notification dampening is performed after AI engine 110 evaluates the test result data that is returned to it by the agents and has updated the error state data accordingly. Thus, at that time, agent dampening is performed by determining the number of agents that detected the error. If the number of agents detecting the error exceeds the agent number threshold, notification is provided to users. Similarly, at this time, the time that the error was detected is subtracted from the time that the notification system performs its evaluation. If the time is greater than the time threshold, notification of the error state is provided to users. In one embodiment of the present invention, notification is provided only if both the error persistence threshold and agent dampening threshold have been exceeded.

If the error is of a certain type and it exceeds the configured dampening parameters, follow-up testing may be performed. Consequently, tests can also be initiated or triggered upon the occurrence of events. Such events include, for example, new devices detected on a network, new ports being opened, issuance or announcement of a new vulnerability (e.g., causing a new plug-in to be put into the system), and time-based events. For example, if a network-layer error occurs, a traceroute follow-up test may be performed to illustrate the network path between the reporting agent and the errored server. DNS follow-up testing can be performed in the event that a DNS error is reported. This test performs an exhaustive depth-first traverse of the entire DNS tree for the errored server. Vulnerability follow-up testing may be performed for a port scan test that reports a new open port. This test will inform the user of any security vulnerabilities visible through the newly detected open port. The results of the scan will be sent to the user through encrypted e-mail.

Follow-up testing may also be performed in response to a condition other than an error detected by the system. For example, when a new security vulnerability is detected the system can perform a scan against all configured port scan tests for the new vulnerability and inform the user if the targets of his tests are vulnerable. The user is able to define what level of security vulnerability is sent to him, and when such a condition is detected the information is sent to the user through encrypted e-mail.

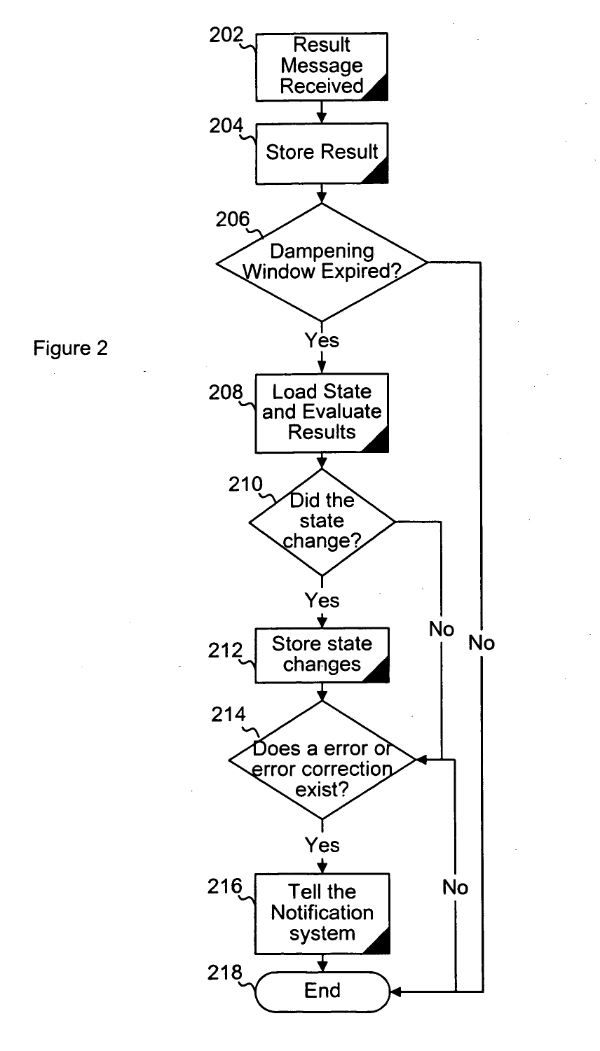

FIG. 2 is a flow chart for a method for maintaining and reporting an error state of a computer network after receiving a result message from an agent during monitoring of the computer network according to an embodiment of the present invention. The method can be performed by any combination of hardware and software. The method begins in step 202 by receiving a result message from an agent after the agent has performed a test and received the results. Preferably, collector 104 receives the results returned by the agent. Collector 104 preferably includes a database into which the result message is stored. In step 204, the result received from the agent is stored. In step 206, the collector determines whether the dampening window has expired.

If the dampening window has not expired, the method ends in step 218 for the particular result message received. If the dampening window has expired, the current error state is preferably loaded into a random access memory (RAM) cache, and the results are evaluated in step 108. To evaluate the results of the tests, the results are evaluated in light of the current error state maintained by the agent for the particular test being performed. If required, the error state is updated, as described in more detail below. An exemplary error state evaluation and update routine is provided in computer listing 1 at the end of the present specification.

In step 210, the method determines whether the error state changed (based on the evaluation of the result message). If the error state has changed, the results are stored in the database in step 212. The new error state is preferably stored through an update of the database rather than storage of the entire error state record. Thus, the current error state supersedes the previous error state. In this embodiment of the present invention, the stored error state is reflective of the current error state of the system at any point in time. In another embodiment of the present invention, the error state information is stored as a new error state record. In this manner, a history of the changes in the error state is readily available. Preferably, to avoid unnecessary database operations, the error state is not stored in the database if there is no change in the error state.

After the new error state has been stored if there was a change in the error state or after the determination is made that there was no change in the error state, the method continues in step 214 with the step of determining if an error or error correction exists. If such error or error correction exists, the notification system is advised of the error or error correction in step 216. The notification system determines whether the notification dampening parameters (described above) have been satisfied to provide notification of the error or error correction to the user. The method then ends in step 218 for the current result message.

The present invention can be implemented on a centralized server or in a distributed manner. In one centralized server embodiment, for example, all result messages are passed to the centralized server for processing. Agent processes can be implemented as separate threads executing on the centralized server.

In one distributed embodiment of the present invention, different functions in the method can be performed by different servers. For example, each module of the system can operate on a separate server. The modules can then communicate with one another using a communication protocol such as TCP/IP. System modules include agents 102a, 102b, . . . 102n, AI engine 110, and notification system 112. Other system modules can be included as well.

The distributed embodiment of the present invention can be implemented using any combination of a plurality of servers. For example, the agents can be implemented on one or more servers and the evaluation functions of the present invention implemented on another server.

The errors that are tracked by the present invention can relate to any network condition that is desired to be monitored. In one embodiment of the present invention, there are twelve categories of errors that are tested. These general categories of errors are (1) general errors; (2) web & transaction test errors; (3) defacement test errors; (4) secure certificate test errors; (5) port scan and port scan range test errors; (6) email errors; (7) Specific SMTP-related errors; (8) Specific POP-related errors (9) DNS server, cluster & domain security errors; (10) TLD server errors; (11) DNS follow-up errors; and (12) ping errors. The particular errors tested for in the twelve categories of tests and descriptions are provided in tables 1-12.

TABLE 1
General Errors

| Error Type | Description |
|---|---|
| Connection Timeout | The connection attempt has timed out. |
| | Attempts to connect are taking longer |
| | than the time period specified under the |
| | Test Parameters. |
| Connection Refused | The connection is failing to complete. |
| | This is usually due to the service or |
| | server having become unbound from the |
| | proper port. |
| DNS LookUp Failed | This error occurs when the Domain |
| | Name System is unable to translate the |
| | provided site name (e.g. |
| | www.example.com) into a valid Internet |
| | Protocol Address. This may be due to the |
| | DNS server being very busy, overloaded |
| | with traffic, or temporarily down. |
| Host/Network Unreachable | The connection is failing to complete, but |
| | it is apparently not a failure of the system |
| | specified for testing. Most commonly this |
| | is an error resulting from the Internet or |
| | network being “broken”. Although rare, |
| | it also may be due to an inadvertent |
| | routing or firewall setting or problem. |
| Hung Server | This error occurs when the server has |
| | died but the system is still listening on |
| | the server Port. This is determined |
| | because Agents are able to establish the |
| | network-layer connection but following |
| | that connection the Agents are not able to |
| | interact with the application-layer server. |
| Low Throughput | Although the connection has been |
| | established, a specific item (URL link) or |
| | collection of items are taking longer to |
| | download than the Threshold Period |
| | specified in the Parameters for this Test. |
| | Both the View Results page and the e- |
| | mail Notification message provide you |
| | with a specific identification of the link |
| | or links exceeding the Threshold Period. |
| | This may be the result of unusually heavy |
| | traffic on the site or the specific item(s) |
| | being located on a different server with |
| | network congestion or system |
| | configuration affecting the necessary |
| | transfer of data. Often this is observed |
| | with regard to banner ads and other |
| | remote hosted media. |
| Low Total Throughput | Although the connection has been |
| | established, and no specific item (URL |
| | link) is by itself taking longer to |
| | download than the Threshold Period |
| | specified in the Parameters for this Test, |
| | the overall sum of all Times for all items |
| | comprising the page is over the |
| | Threshold Period. This may be the result |
| | of the Threshold setting being too low, |
| | unusually heavy traffic on the site, or the |
| | specific item(s) being located on a |
| | different server which has network |
| | congestion or system configuration which |
| | is affecting the necessary transfer of data. |
| Unknown | Although rare, it is possible that some |
| | unknown event or error may occur during |
| | the testing process. This may be the result |
| | of a connection being severed in the |
| | midst of reporting a condition or |
| | transferring test data, or simply being |
| | terminated so abruptly that there is no |
| | clear reason or error code known to the |
| | system. While this label may seem |
| | unhelpful, it is inappropriate to guess at |
| | the cause. Normally follow-up testing |
| | will automatically occur. In most cases |
| | the results from other Agents can be |
| | referred to in order to better understand |
| | the origin of this Unknown condition and |
| | the status of the site. |

TABLE 2
Web & Transaction Test Errors

| Error Type | Description |
|---|---|
| Error #400 - Bad Request | There is a problem with resolving the |
| | requested URL. This may simply be due |
| | to an incorrect URL syntax. |
| Error #401 - Unauthorized | This error results when an attempt to |
| Access Attempted | connect to a protected site is made |
| | without the proper encryption ID or |
| | password for entry. The first step in |
| | resolving this error is to confirm that the |
| | provided URL is correct for the website |
| | and that no password is required to |
| | access the intended page. |
| Error #403 - Connection | This error occurs when a server denies |
| Refused by Host | access because of the originating domain, |
| | security restrictions, or the lack of a |
| | password. More specifically this error |
| | occurs when attempting to connect to a |
| | site requiring registration for use. The |
| | first step in resolving this error is to |
| | confirm that the provided URL is correct |
| | for the website and that no password is |
| | required to access the intended page. |
| Error #404 - File | This error occurs when the specified |
| Not Found | HTML document requested cannot be |
| | found at the specified location. The 404 |
| | error generally result from a syntactical |
| | error due to a document or file name |
| | change or accidental deletion. The first |
| | step in remedying this error is to ensure |
| | that: a) the website has all necessary files; |
| | b) the files are properly named and |
| | identified; c) the files are in the |
| | appropriate and proper directories; and d) |
| | you have maintained proper updates |
| | within your files of where links point. |
| Error #502 - Service | This error occurs when the server is |
| Overloaded | experiencing high traffic load without the |
| | ability to process all the requests. This |
| | error will be removed when either a) the |
| | traffic to the site decreases, or b) the |
| | server's ability to process all requests is |
| | improved through: i) upgrade, ii) |
| | maintenance, or iii) increasing provided |
| | levels of connectivity. The first step in |
| | remedying this error is to ensure that |
| | there is indeed a large volume of traffic |
| | hitting your site. If the traffic is light you |
| | should perform system maintenance to |
| | ensure that the server is not stuck with |
| | hung processes occupying CPU time. If |
| | the system is properly in tune it may be |
| | necessary to consider additional memory, |
| | CPU upgrades, hard drive upgrades, |
| | adding additional servers, or increasing |
| | the connection bandwidth to help |
| | increase the number of requests that can |
| | be processed. |
| Error #503 - Service | This error occurs when the access |
| Unavailable | provider for the site, gateway to the site, |
| | or the actual server for the site is |
| | unavailable or busy to the point that it is |
| | effectively down. Please check the server |
| | and confirm its operability. |
| Low Transaction | Attempts to complete the transaction are |
| Throughput | taking longer than the Transaction |
| | Threshold Time specified under the Test |
| | Parameters. (Similar to Low Total |
| | Throughput for the Web Test, but applied |
| | to the entire transaction.) |
| Match Error | This error occurs when the information |
| | given for pattern matching is not found. |

TABLE 3
Defacement Test Errors

| Error Type | Description |
|---|---|
| Source Modified | The source code for the web page |
| | checked differs from the source code |
| | input during the setup of the defacement |
| | test. |
| | For sites that change regularly, there is an |
| | option that allows you to specify the |
| | number of lines that may differ from the |
| | original source code - in this case, the |
| | “Source Modified” error, means that the |
| | source code differed by more than the |
| | allowable number of lines. |
| | This error may have been caused by |
| | someone updating your web site without |
| | updating the defacement test. If this is the |
| | case, please update your defacement test |
| | to the latest source code. |

TABLE 4
Secure Certificate Test Errors

| Error Type | Description |
|---|---|
| Connection Warning | Unable to connect to the target/port with |
| | secure sockets layer (SSL) to conduct the |
| | test. |
| Can't Get Issuer Cert | The issuer certificate could not be found. |
| | This occurs if the issuer certificate of an |
| | untrusted certificate cannot be found. |
| Cert Not Yet Valid | The certificate is not valid now, but it |
| | will be valid in the future. |
| Cert Has Expired | The valid dates for the certificate are in |
| | the past. |
| Self Signed Cert | The passed certificate is self signed and |
| | the same certificate cannot be found in |
| | the list of trusted certificates. |
| Self Signed Cert in Chain | The certificate chain could be built up |
| | using the untrusted certificates, but the |
| | root could not be found locally. |
| Can't Get Local Cert | The issuer certificate of a locally looked |
| | up certificate could not be found. This |
| | normally means the list of trusted |
| | certificates is not complete. |
| Can't Verify First Cert | The issuer certificate of a locally looked |
| | up certificate could not be found. This |
| | normally means the list of trusted |
| | certificates is not complete. |
| Host Mismatch | The host given in the key retrieved from |
| | the target website does not match the host |
| | (target) given in the setup of the test. |
| Key Mismatch | The certificate key retrieved from the |
| | target web site does not match the |
| | certificate key given in the setup of the |
| | test. |
| Other Error | Other error not specified above. |

TABLE 5
Port Scan and Port Scan Range Test Errors

| Error Type | Description |
|---|---|
| Port(s) Modified | The state for one or more ports does not |
| | match the baseline for when the test was |
| | started. (i.e., a port is open that should be |
| | closed, and/or a port is closed that should |
| | be open.) |

TABLE 6
E-Mail Test Errors

| Error Type | Description |
|---|---|
| Mail Propagation | It is taking longer than the time specified |
| Timeout | in the Test Parameters for an e-mail |
| | message to go from the SMTP server to |
| | the specified POP server. This error |
| | typically occurs when e-mail servers are |
| | under an unusual amount of load due to |
| | high message volume. However, it is |
| | advisable to check that all SMTP servers |
| | in the path between the Internet-facing |
| | MX servers and the end-user POP servers |
| | are functioning and accepting messages |
| | properly. |
| Timeouts | Each component process of the e-mail |
| | test is monitored for proper completion |
| | within a specified period of time. Should |
| | an operation timeout - that is to say it |
| | took longer than the specified threshold |
| | Parameter - the operation failing is noted |
| | and reported. For the involved e-mail |
| | propagation processes, the system detects |
| | and delivers notifications for the |
| | following situations: |
| | SMTP Related |
| | Connect Timeout |
| | Banner Timeout |
| | HELO Timeout |
| | HELO Response Timeout |
| | FROM Timeout |
| | FROM Response Timeout |
| | TO Timeout |
| | TO Response Timeout |
| | DATA Timeout |
| | DATA Response Timeout |
| | Message Send Timeout |
| | Message Send Response Timeout |
| | QUIT Timeout |
| | QUIT Response Timeout |
| | POP Related |
| | STAT Timeout |
| | STAT Response Timeout |
| | SIZES Timeout |
| | SIZES Response Timeout |
| | Delete Timeout |
| | Delete Response Timeout |

TABLE 7
Specific SMTP Related Errors

| Error Type | Description |
|---|---|
| The HELO command | This command is used to identify the |
| received an error | sender-SMTP to the receiver-SMTP and |
| | visa-versa. The expected OK reply |
| | confirms that both systems are in the |
| | initial state, that there is no transaction in |
| | progress, and that all state tables and |
| | buffers are cleared. The returned error |
| | indicates that one or more of these |
| | conditions are not true. The first step in |
| | remedying this error is to check the |
| | SMTP server and confirm that it is |
| | functioning properly, that the state tables |
| | are clear, and that no transaction has |
| | become hung. |
| The MAIL FROM | This is a very basic SMTP command and |
| command failed | failure is indicative of a serious error in |
| | the SMTP configuration and operation. |
| | There are many situations that might |
| | cause this condition. All of them are |
| | critical system errors. The first step in |
| | remedying this error is to check the |
| | SMTP server and log files and restart the |
| | system. |
| The RCPT TO | This error occurs for a variety of |
| command failed | situations stemming from a problem with |
| | the indicated recipient. The most |
| | common situations are where the |
| | indicated recipient for the e-mail is |
| | unknown to the SMTP system, the |
| | recipient is not local and the mail is to be |
| | forwarded, or the recipient's storage is |
| | full. All of these conditions should not |
| | exist for the e-mail address designated for |
| | testing. The first step in remedying this |
| | condition is to confirm that the proper e- |
| | mail address has indeed been specified. It |
| | is also advisable to confirm that the |
| | system hard drive is neither full nor |
| | corrupted. |
| The DATA command | This error generally occurs when the mail |
| has failed | transaction is incomplete (such as lacking |
| | a recipient) or necessary resources |
| | required by the mail system are not |
| | available. The first step to resolving this |
| | condition is to confirm that the specified |
| | e-mail address is correct and currently |
| | enabled on the system. |
| Error After Data Input | The anticipated Success code was not |
| | returned after sending the Data and the |
| | End of Data code to the SMTP server. It |
| | is very difficult to suggest a specific |
| | reason for this type of error. The first step |
| | in resolving this condition is to check the |
| | SMTP server log files for an indication of |
| | where the fault has occurred. |
| Unknown Error | Although unlikely, there is a possibility |
| | that the SMTP test will generate an |
| | unknown or unanticipated error - usually |
| | because the connection was suddenly cut. |
| | In the event that such an error occurs, |
| | Agents will report the condition as |
| | unknown. |

TABLE 8
Specific POP Related Errors

| Error Type | Description |
|---|---|
| Invalid Connection | This error results from an error within |
| Banner Received | your POP server setup. While the TCP |
| | connection can be established, your |
| | system is not sending the anticipated or |
| | acceptable reply. Your first steps in |
| | remedying this error are to check your |
| | POP server configuration for errors - |
| | syntactical or logical. You should also |
| | review your log files as they may well |
| | directly identify the service that is failing |
| | or conflicting and generating this error as |
| | a result. |
| Invalid UserName | Although a connection can be made to |
| | your specified e-mail server the provided |
| | e-mail Username is returning as invalid. |
| | The first step in resolving this situation is |
| | to confirm that the Username provided in |
| | the Test Parameters is correct. A check |
| | should also be made to confirm that a |
| | corresponding account for the Username |
| | has been established with the POP |
| | system, and that it is utilizing the proper, |
| | current and uncorrupted data-file for |
| | account information. |
| Bad Password | Although a connection can be made to |
| | the specified e-mail server the provided |
| | e-mail Password is returning as invalid. |
| | The first step in resolving this situation is |
| | to confirm that the Password provided in |
| | the Test Parameters is correct. A check |
| | should also be made to confirm that the |
| | POP system is utilizing the proper, |
| | current and uncorrupted data-file for |
| | account information. |
| Successful Login, | The test message sent to the e-mail |
| No Messages Waiting | address specified under the Test |
| | Parameters has not yet been received. |
| | The system tests designated e-mail |
| | address by first sending a test message |
| | and then retrieving that test message. |
| | While it appears that the Send portion of |
| | the test has been successful, the message |
| | is not appearing in the mailbox. The first |
| | steps in resolving this condition are to: a) |
| | confirm that any involved firewalls or |
| | routers are functioning normally; and b) |
| | that a forward command has not been |
| | inadvertently added to the test e-mail |
| | account. |
| Error Retrieving Message | The system has received erroneous |
| Summary Information | information regarding the Scan Listing |
| | for the test message - this is the |
| | information used by an e-mail system to |
| | identify messages and determine whether |
| | they have been previously read or not. As |
| | there are lots of different types and |
| | configurations of POP systems in use, it |
| | is very difficult if not impossible to state |
| | the specific cause simply because this |
| | error condition has been detected. The |
| | first step in resolving this situation is to |
| | check the POP system configuration file |
| | to confirm that all settings are indeed |
| | correct. A review of the POP system logs |
| | may also yield help in uncovering the |
| | problematic settings or application. |
| Error Retrieving | Although a connection can be made to |
| a Message | the specified e-mail server and a test |
| | message has been identified as present |
| | and ready for retrieval, the system has not |
| | been able to actually retrieve the test |
| | message. As there are lots of different |
| | types and configurations of POP systems |
| | in use, it is very difficult if not |
| | impossible to state the specific cause |
| | simply because this error condition has |
| | been detected. General steps to take that |
| | may resolve the condition include |
| | checking the POP system configuration |
| | file to confirm that all settings are indeed |
| | correct; b) checking that auto encryption |
| | is not being engaged; and c) checking |
| | that any involved routers or firewalls in |
| | use are properly configured and |
| | functioning normally. A review of the |
| | POP system logs may also yield help in |
| | uncovering the problematic settings or |
| | application. |
| Locking Error | This condition results when the system |
| | detects that another entity is connected to |
| | a specific POP account that has been |
| | established for system testing. Only one |
| | user at a time may normally be connected |
| | to the same POP account. This is a |
| | condition imposed to help avoid |
| | confusion that might arise if one user was |
| | attempting to retrieve a message at the |
| | same time another user was attempting to |
| | delete the message. Agents involved in |
| | e-mail system testing actively compete |
| | with one another for access to the POP |
| | system. However, the system is aware of |
| | this competition and will only respond to |
| | the Locking Error condition if none of |
| | the Agents were able to successfully |
| | connect to the indicated e-mail test |
| | account during an iteration of testing. |
| | The most common cause of this condition |
| | is the presence of a stale lock remaining |
| | from a prior successful connection. |
| Quit Error | Although highly unlikely to occur |
| | without encountering an earlier fatal |
| | error, this condition will arise when the |
| | expected ok response is not returned |
| | following the Quit command. |
| Unknown Error | Although unlikely, there is a possibility |
| | that the POP test will generate an |
| | unknown or unanticipated error - usually |
| | because the connection was suddenly cut. |
| | In the event that such an error occurs, |
| | Agents will report the condition as |
| | unknown. |

TABLE 9
DNS Server, Cluster and Domain Security Errors

| Error Type | Description |
|---|---|
| Empty answer section | The answer section of the reply from the |
| | DNS server was empty. This means that |
| | there was not an exact match for the |
| | query given to the server. This solution |
| | for this could be as simple as changing |
| | the query that your test is using. In some |
| | cases this can indicate a problem with the |
| | configuration of your DNS server. |
| Empty Reply | The DNS server responded with an |
| | empty response - no data was sent back. |
| RR type mismatch | The RR handed back in the answer |
| | section did not match the type that the |
| | server was asked for. |
| DNAME mismatch | The DNAME of the record returned by |
| | the server did not match the DNAME |
| | that the server was asked for. |
| Non-authoritative answer | The server did not hand back an |
| | authoritative answer. This may be |
| | because you queried a server that is not |
| | authoritative for the appropriate zone, or |
| | perhaps because there is a configuration |
| | problem with the server queried. |
| RCODE was not NOERROR | The DNS server responded with an error |
| | code of something other than |
| | NOERROR. |
| Incorrect Record | A record was returned that was not in the |
| | stored state. (The stored state is data |
| | input when setting up a test.) |
| Missing Record | The returned data did not include all the |
| | records in the stored state. (The stored |
| | state is data input when setting up a test.) |
| Multiple Answers (rare error) | The DNS server responded with more |
| | than one answer to an SOA query. (For |
| | an SOA query there should be only one |
| | answer.) |
| Incorrect Answer Count | A SOA query returned more than one |
| | response. |

TABLE 10
TLD Server Errors

| Error Type | Description |
|---|---|
| TLD Server Reports | This is a serious error that indicates that |
| Domain Unknown | the TLD server queried did not know of |
| | the specified domain's existence. Stated |
| | simply, this implies that if someone were |
| | to ask the specified TLD server about the |
| | indicated domain name and how to find |
| | it, the request would fail. Remedy of this |
| | error can only be made by contacting the |
| | Registrar responsible for maintaining the |
| | failing Domain. To assist the Registrar |
| | you should provide them with a list of the |
| | TLD servers that know of the domain as |
| | well as those that do not. |

TABLE 11
DNS Follow-up Errors

| Error Type | Description |
|---|---|
| Lame Delegation | This error occurs when the indicated host |
| | (name server) does not contain a Start of |
| | Authority (SOA) record for a domain |
| | name either because it does not exist or |
| | the name server does not believe it has |
| | authority for that domain. For example, |
| | in normal operation a query to a “parent |
| | server” (for .com, .net, .edu, etc . . .) is |
| | directed to the system believed to hold |
| | the relevant DNS information. If that |
| | system has no information or believes |
| | itself not to be the authority for that |
| | Domain it will refer the query to the |
| | higher level system. The result is a loop |
| | as the higher system redirects the query |
| | back to the “lame” system it believes to |
| | hold the records. A simple typographical |
| | error can give rise to this error. You |
| | should check the Domain Name Server |
| | entries for the error, or if the DNS record |
| | is maintained by a third party such as |
| | your domain registrar, contact them and |
| | confirm that they have the appropriate |
| | records updated and available. |
| Primary Mismatch | The control and integrity of DNS |
| | information for a particular zone is |
| | maintained hierarchically. Typically this |
| | is done with a single “Primary” data |
| | server and multiple secondary |
| | “Authoritative” servers. The |
| | Authoritative servers periodically query |
| | the Primary server to obtain a copy of the |
| | most current DNS information. A |
| | Primary Mismatch error occurs when the |
| | information provided by an Authoritative |
| | server in the zone does not match the |
| | information provided by the Primary |
| | server for the zone. When conducting this |
| | test, the system uses the server referenced |
| | in the zone's Start of Authority (SOA) |
| | record as the Primary server. The results |
| | of a query to this system are compared to |
| | the query results from all other |
| | Authoritative servers for the zone. To |
| | remedy this error you should check your |
| | DNS files and confirm that the proper |
| | record is available and that the interval at |
| | which the Authoritative servers query the |
| | Primary server for record refresh is not |
| | unusually large. |
| Server Did Not Respond | Because of the nature of the DNS follow- |
| | up test it is not possible to distinctly state |
| | whether this is the result of the Name |
| | Server having become hung or simply |
| | unreachable over the network. The |
| | system does perform traceroute tests for |
| | errors of this type and the results are |
| | available through the Results Page for the |
| | corresponding test. |
| Unknown Record | This error occurs when an authoritative |
| | response for the requested DNS record |
| | type could not be found, such as querying |
| | for a Start of Authority (SOA) on a host |
| | (name server) that contains Mail |
| | Exchange (MX) records but no SOA |
| | records for that Domain. To remedy this |
| | error you should check the Domain Name |
| | Server entries for the error, or if the DNS |
| | record is maintained by a third party such |
| | as your domain registrar, contact them |
| | and confirm that they have the |
| | appropriate records updated and |
| | available. |

TABLE 12
Ping Errors

| Error Type | Description |
|---|---|
| Bad Connection | The host target of the Ping Test has |
| | rejected the Ping connection. For one |
| | reason or another the intended target for |
| | the test is refusing to allow Ping |
| | connections from the Agents. This is |
| | more sever than a simple filter, as the |
| | fundamental network settings are |
| | blocking all connections from the IP |
| | addresses or the Agent or Agents that |
| | have generated this message. Confirm |
| | that your network settings are as |
| | intended. |
| Network/Host/Protocol/Port | As with Bad Connection above, there is a |
| Unreachable | failure to complete the connection. |
| | However, based upon the return code it is |
| | known which element - the Network, |
| | Target Host, Protocol, or Port - has been |
| | detected to be Unreachable. This may be |
| | due to the network being “broken”, the |
| | Host being down, or the Protocol or Port |
| | having inadvertently been disabled or |
| | firewalled. |
| Checksum Error | Checksum should be the 16-bit one's |
| | complement of the ICMP message |
| | starting with type (a 0 for a simple echo). |
| | In simple English, this is a mathematical |
| | value that should represent the contents |
| | of the packet. Occasional checksum |
| | errors will occur and are a natural and |
| | automated part of network operation, and |
| | every protocol suit has mechanisms for |
| | detecting and dealing with them. When |
| | encountered in Ping this error may |
| | indicate a serious error. This may be an |
| | indication that the NIC card of the host is |
| | bad or has faulty memory, or perhaps |
| | even that ICMP spoofing is occurring. |
| Duplicate Packets | The remote host has returned duplicate |
| | packets. Duplicate packets should never |
| | occur and may be caused by a |
| | inappropriate link-level re-transmission. |
| | An occasional duplication may not be |
| | cause for serious alarm. To resolve this |
| | situation you should review the system |
| | configuration to confirm that arrant echo |
| | commands or duplicate re-transmission |
| | variables are not present. |
| Packet Loss | The Ping Packets are suffering loss and |
| | or damage to such an extent that what is |
| | returning is not reliable. Minor Packet |
| | loss is usually due to network congestion. |
| 100% Packet Loss | 100% Packet Loss, usually seen as |
| | “request time out” if ping is run from a |
| | command prompt, is most typically due |
| | to the target host, or the hosts network |
| | having been set to block ping packets. It |
| | is possible that the network may have |
| | been partitioned or otherwise “broken”. |
| Filtering | There is an apparent Ping Filter in place |
| | on the destination host, or the hosts |
| | network. This filter is apparently working |
| | to “Filter out” the Ping packets being sent |
| | by the system, and as such it is not |
| | possible to return any data of value to |
| | you. In some instances ISP's may engage |
| | ICMP filters on their own. To resolve this |
| | situation you can either remove the filter |
| | entirely, or adjust the filter to permit Ping |
| | tests from the Agents - a list of the |
| | Agents and their IP addresses can be |
| | found on any of the Charts provided with |
| | the Web tests. Depending on how such |
| | Filtering, this condition may be detected |
| | and reported as 100% Packet Loss. |
| Latency Error | The Maximum and or Average measured |
| | round trip time (“Latency”) of the |
| | Packets involved in the Ping test is above |
| | the threshold established in the |
| | Parameters for this test. This may be the |
| | result of either unusually heavy traffic on |
| | the host system or network congestion |
| | encountered in rout to or from the host |
| | system. Confirm as well that the |
| | established Threshold value for this test |
| | is reasonable. |
| Redirected | The attempt to connect to the specified |
| | Target has been redirected to another |
| | network or host. As this is not the host or |
| | network of intention this Redirection has |
| | been classified as an error. If the Target is |
| | undergoing maintenance, or you have |
| | imposed redirection for a specific |
| | purpose this detection is hopefully no |
| | surprise. |

The tests that produce these errors can operate continually or on a demand basis. In either event, the test compares an observed state to a baseline state. The baseline can be user-entered or system generated (e.g., captured by the system). Moreover, the baseline can be altered or reset during system operation. The results of the comparisons can indicate changes or deltas in the network error state. This error state and/or the deltas can be reported to users. For example, as described above, the error states and/or deltas are reported at the expiration of a notification window.

The tests can be classified into two general categories. Security tests determine changes in the network that may reflect security breaches. Performance tests determine changes in the network that may indicate the system is not performing as designed, or that lead to inefficient operation of the network.

Security tests include defacement tests, DNS and cluster domain tests, port scan and port scan range tests, secure certificate tests and cluster and domain security tests.

The defacement test compares a web page to a pre-stored baseline version of the web page. Generally, the test compares each object in the web page to each object in the pre-stored web page. The user is notified of any changed to the web page from the baseline.

The secure certificate test ensures that a certificate used by a secure web server is both correct and matches a pre-stored certificate, which is used for comparison. The pre-stored certificate can be supplied by a user of the system or a third party. The secure certificate test can be used to detect website hijacking using various methods, including DNS or BGP routing hijacking. Because the present invention provides monitoring from multiple points across the Internet, detection of localized hijacking attempts is possible.

The port scan test scans a single IP address for all 65535 possible TCP ports and reports changes in the stored port states. The port scan range test scans a range of IP addresses daily against a well known set of ports. The well know set of ports is preferably the setoff ports allocated to a particular service. In addition, preferably, once a week the entire set of 65535 ports is scanned for the range of IP addresses. In both cases, for the port scan range test, the results (i.e., the status of the ports)is compared against a stored state. For the port scan range test, preferably two comparison states are stored. One of the comparison states corresponds to the well known ports, and the other comparison state corresponds to the full scan. When the port scan test is initially configured, a complete vulnerability scan is preferably run against the open ports and is sent to the user over encrypted e-mail. Also, preferably the system allows the user to initiate vulnerability scans on demand through the user interface.

The DNS domain security test compares a DNS to a pre-stored baseline version of a DNS. The user is notified of any change to the DNS from the stored DNS. The DNS cluster security test applies the DNS domain test to a cluster of servers. The DNS cluster security test can be used to provide additional criteria for notification dampening. For example, the DNS cluster security test allows a user to specify that notification shall occur only when a certain number of servers exhibit an error condition.

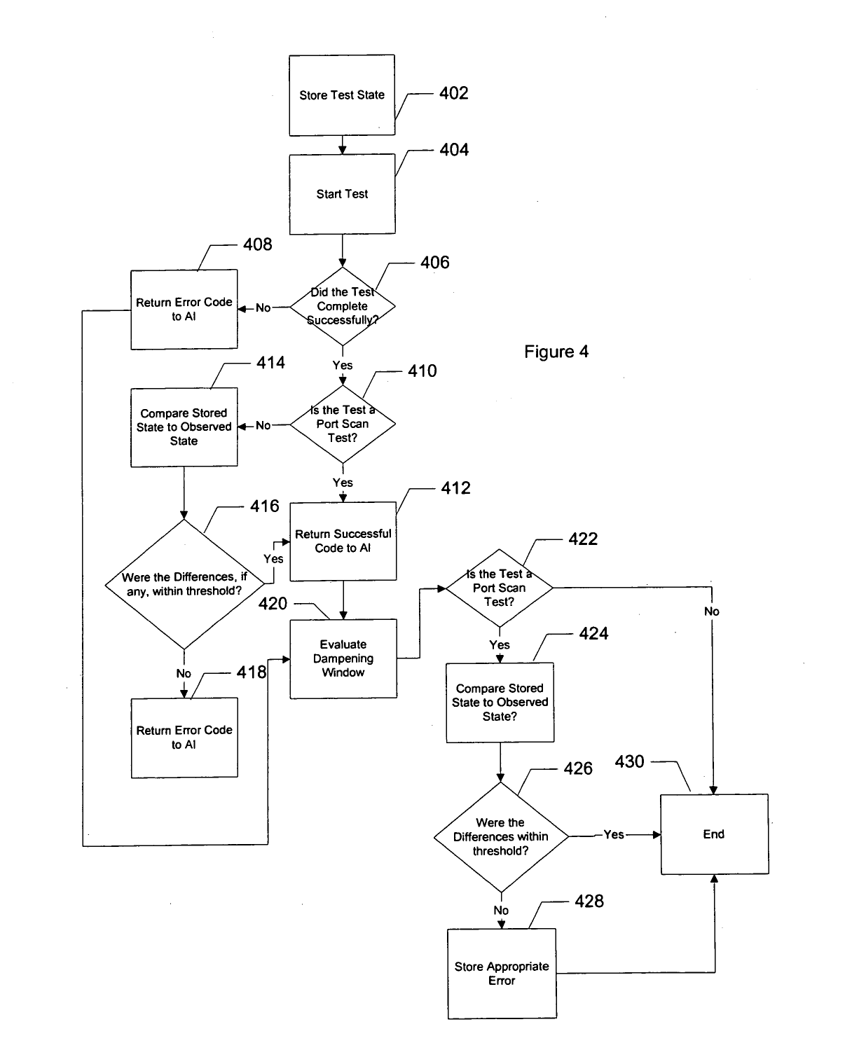

Each security test preferably follows proceeds in a similar manner. FIG. 4 is a flow chart for a method for performing a security test according to an embodiment of the present invention. The method begins in step 402 with the step of storing a baseline test state. The baseline test state is the baseline for the particular entity that is being examined. For example the baseline test state for a web page defacement test is the true web page. The test state can be user-entered or system generated. In step 404, the security test is started. The test can be started, for example, by initiator a command from 108 as described above.

In step 406, an evaluation is made to determine if the test completed successfully. For example, an agent can perform the evaluation. If the test does not complete successfully, an error code is returned in step 408. For example, the error code can be returned to AI engine 110 through initiator 108. If the test does complete successfully, the method continues in step 410 by determining whether the test is a port scan test. If the test is a port scan test, a success code is returned in step 412. For example, the success code can be returned to AI engine 110 through initiator 108.

The port scan test is treated separately in the preferred embodiment because the comparison of the stored state to the observed state is preferably performed by AI engine 110 rather than an agent. The reason for this is to reduce complexity of the agent as the port scan test is a more complex test than the other tests. In an alternative embodiment of the present invention, the port scan test is performed by one or more agents. In the alternative embodiment of the present invention, the port scan test is treated as other security tests.

If the test is not a port scan test, the method continues in step 414 with the step of comparing the stored baseline state to the observed state (for example, as measured by an agent). In step 416, a determination is made as to whether there are any differences. Optionally, a difference threshold can be set for a test. The difference threshold allows for differences between the observed state and the baseline state. For example, the difference threshold can be a number of differences allowed between the observed and baseline states. An error condition exists if the number of differences exceeds the difference threshold. If there are no differences (or the differences, if any, are within the difference threshold where a difference threshold is used), the method continues in step 412 with the step of returning a successful code. For example, the success code can be returned to AI engine 110 through initiator 108. If there are no differences (or the differences, if any, are outside the difference threshold when the difference threshold is used), the method continues in step 416 with the step of returning an error code. For example, the error code can be returned to AI engine 110 through initiator 108.

If the method takes the proceeds through steps 408 or 412, the method continues with the step of evaluating the dampening window. The dampening window is evaluated to determine whether any error states for any tests should be evaluated so that the corresponding error state data structures can be updated. If the dampening window has expired, the error states are evaluated using the error and/or success codes returned by the tests and the corresponding error data test structures are updated accordingly.

The method continues in step 422 with the step of determining whether the test is a port scan test. If the test is not a port scan test, the method ends in step 430. If the test is a port scan test, the method continues in step 424 with the step of comparing the stored baseline state (corresponding to port allocations, assignments and port states (open/closed)) with the observed state. If there were no differences (or the differences, if any, are within the difference threshold when the difference threshold is used), the method ends in step 430. If there were differences (or the differences are no within the difference threshold when the difference threshold is used), the method continues in step 428 with the step of storing the appropriate error corresponding to the port scan error. The method then ends in step 430.

Performance tests include web and transaction tests, e-mail tests, SMTP tests and POP test, TLD Server tests, DNS and cluster server tests, DNS follow-up tests and ping tests.

The web and transaction tests monitor either a single web page or a series of web pages. They not only download the index page but also each object that the index page references. The system maintains detailed error and performance data on each object in the page. In the case of the transaction test, the system is also capable of performing pattern matching, to detect back-end errors that do not result in an http error.

The e-mail test is preferably a combination of the SMTP and POP tests (described in detail below). The e-mail test uses the SMTP test's send message functionality and the POP test's fetch message functionality to calculate a propagation time of a message through a site's e-mail system. If the message's propagation time is greater than a pre-determined propagation time or the message does not reach the e-mail server an error condition is raised.

The SMTP test takes an e-mail address as an argument and attempts to send a message to that user using the DNS MX records for the address to determine which server to connect to.

The POP test takes a server, username and password that correspond to an e-mail account and attempts to fetch messages from that account. Preferably, any messages sent by the SMTP test are returned to AI system 110 to be used to calculate e-mail propagation times for the e-mail test.

The TLD Server test determines whether a TLD server knows of a one or more pre-stored DNSs. Preferably, the DNSs are sent to the TLD server one-at-a-time. If the TLD server does not return a reference to the DNS, the test fails. The user is notified of the failure.

The DNS server test times a query against a configured DNS server with a configured query. If the query fails the user is notified with the appropriate error (described above). The DNS cluster test tests a group of DNS servers configured with the same query parameters. The cluster configuration of DNS servers allows notification aggregation. That is, notification can be provided only when the test for a certain number of servers in a cluster results in an error.

The DNS follow-up test performs an exhaustive traverse of the entire DNS tree for a fully qualified domain name. This test is performed when another test (web, ping, etc) detects a DNS error to help identify the cause of the problem. For example, the DNS follow-up test detects which servers are exhibiting errors and what kind of errors they are exhibiting, starting with the root TLD servers for the domain name.

The ping test provides information regarding the packet loss an agent detects to the target. In addition, the ping test provides round trip network latency from the agent to the target.

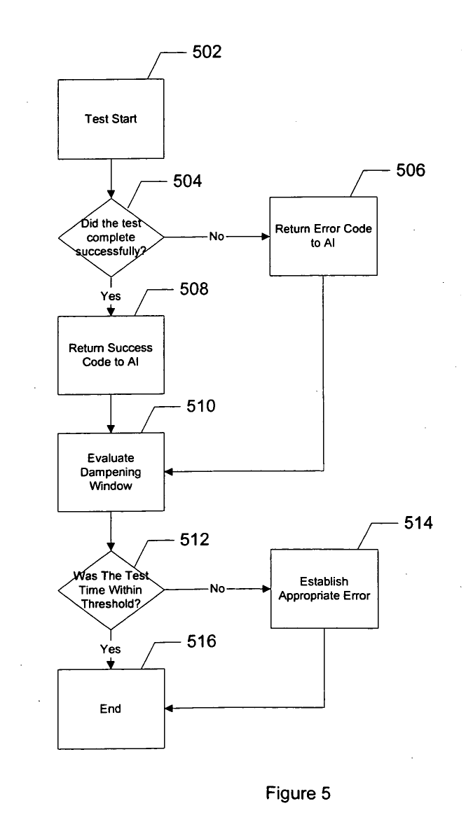

Each performance test preferably follows proceeds in a similar manner. FIG. 5 is a flow chart for a method for performing a performance test according to an embodiment of the present invention. The method begins in step 502 with the step of starting the performance test. The test can be started, for example, by initiator a command from 108 as described above.

In step 504, an evaluation is made to determine if the test completed successfully. For example, an agent can perform the evaluation. If the test does not complete successfully, an error code is returned in step 506. If the test does complete successfully, a success code is returned in step 508. For example, the error or success code can be returned to AI engine 110 through initiator 108.

After the result code (error (step 506 ) or success (step 508 )) is returned, the method continues in step 510 with the step of evaluating the dampening window. The dampening window is evaluated to determine whether any error states for any tests should be evaluated so that the corresponding error state data structures can be updated. If the dampening window has expired, the error states are evaluated using the error and/or success codes returned by the tests and the corresponding error data test structures are updated accordingly.

In step 512, a determination is made as to whether the test was performed within the time threshold (i.e., the dampening window). If the test time was within the time threshold (the dampening interval), the method continues in step 514 with the step of establishing the appropriate error. In step 514, the error state is updated if required. If the test was not within the time threshold or the error data structures have been updated as required, the method ends in step 516.

Exemplary Test Methodology—TLD DNS Test Methodology

A critical component of the DNS structure of the Internet is that top level domain (TLD) name servers must be aware that a given domain name exists. Currently, there are 13 TLD name servers responsible for the generic TLDs (e.g., .com, .gov, .mil, .net, etc.) The 13 TLD name servers are located around the world. In theory, each TLD name server has an identical set of records about the domain name space as it currently exists. However, the TLDs comprise millions of domain listings, and sometimes there are errors. As a result, occasionally some TLDs are not aware of a particular domain name.

The domain name system is based upon recursion. The TLD name server does not know specifically where the requested server is that corresponds to a domain name, but it does have information that should enable it to determine the requested server is. For example, when connecting to a particular website on the Internet, for example, catbird.com, the provided domain name must be resolved to a specific host. A browser typically accomplished this by initiating a query to a randomly assigned TLD name server. At the TLD name server's level, querying on catbird.com or foo.catbird.com should return the same result—that is, the location holding information on catbird.com also provides direction to foo.catbird.com.

However, with millions of records being continually updated, errors do occur. If a record is lost the entire domain is lost. Loss of a domain is often frustrating, time-consuming and can cause significant business losses.

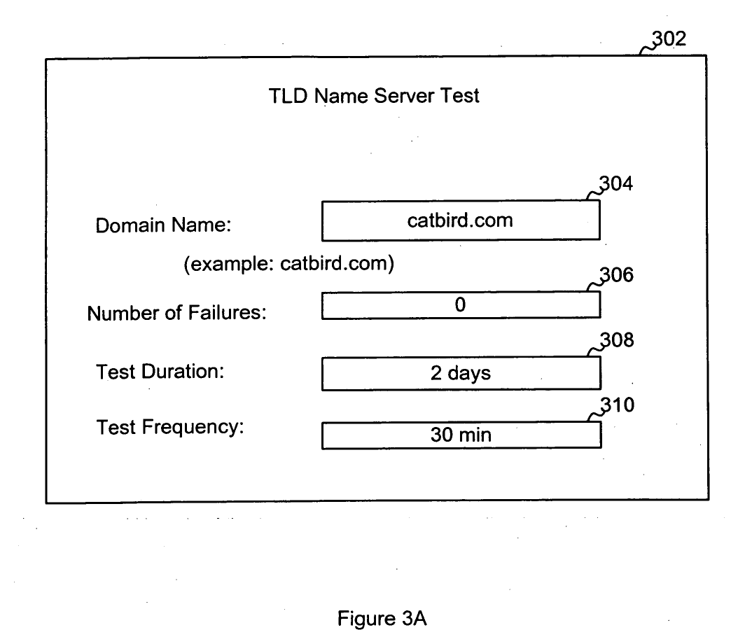

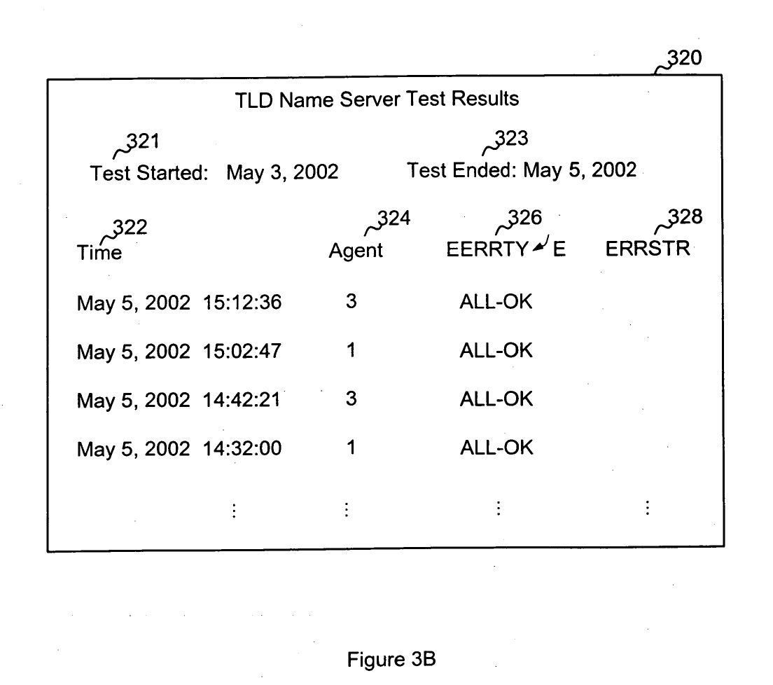

To test the DNS records within a TLD, a user provides a domain name and a threshold number of acceptable failures. In addition, the user can supply (or change default values for) a test duration and a test frequency. An exemplary graphical user interface 302 for allowing a user to provide input for the TLD name server test is illustrated in FIG. 3A. Graphical user interface 302 includes a text edit window 304 for entering a domain name and a text edit window 306 for entering an acceptable number of failures. In addition, text edit window 308 provides a place for a user to enter (or change) a test duration and text edit window 310 provides a place for a user to enter (or change) a test frequency.

The testing sends simple queries to the TLD name servers one at a time. If the TLD name server responds with a reference to the domain it passes the test. If it responds with a reference only to the TLD such as .com or .net, it fails the test. Lack of a response from the TLD is not indicative of a failure. It is possible that the query timed out because the TLD name server is under a heavy load or there is poor connectivity if, for example, connecting to a distant TLD name server.

Each failure of the TLD name server is logged by the test system as described above. Notifications of the failures are sent if the failures exceed the notification damping parameters described above. In general, this will be a single failure. However, as the records take approximately twenty-four hours to update, if a user is continually updating their records it may be more reasonable to detect failure in more than one TLD name server before providing a notification.

FIG. 3B illustrates an exemplary graphical user interface 320 for notifying a user of the results of a TLD name server test according to an embodiment of the present invention. Graphical user interface 320 indicates when the TLD name server test started 321 and when it ended 323. The time each agent performed the test is provided in column 322. Preferably, time is provided in reverse chronological order. The agent performing the test is provided in column 324. An error type is returned in column 326. An explanation of the error is provided in column 328. In the example illustrated in FIG. 3B there were no errors, so no explanation is required in column 328.

The system can also perform a detailed “crawl” of the domain name structure to determine exactly where failures within the recursive records actually occur. By design, if a recursive records returns a bad reference, a parallel record will automatically be chosen and the process continued. Analyzing each and every record is not likely to be beneficial because during the time required to complete the analysis, new updates will have occurred and detected errors corrected and new ones created.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

Computer Code Listing 1: Exemplary Error Result Evaluation Routine

int check_cert_retcode(int session_id,

Cert_Err *prev_err,
Per_Agent_Cert_Result *np,
Cert_Result *w,
int u_time)

```
{
  DEBUG(0, (“cert retcode %d %d %d\n”, np->curr_time.dns,
w->retcode, u_time));
  if (w->retcode > 0) {
    if (!prev_err->err_bad_exist) {
      np->status.err_bad_new = 1;
      np->status.err_bad_reported = 1;
      np->to_report = 1;
    } else {
      if (prev_err->err_bad_reported)
        np->status.err_bad_reported = 1;
    }
    if (u_time > np->latest_time) {
      np->latest_time = u_time;
      /* do not forget to assign the earliest total_time value
        total time so notification would get it */
      /* np->total_time = total_time;
        */
      np->retcode = w->retcode;
      if (np->status.err_bad_exist) {
        np->status.err_bad_repeat = 1;
        np->to_report = 1;
      } else {
        if (np->curr_time.dns == 0)
          np->curr_time.dns = np->prev_time.dns ?
np->prev_time.dns : u_time;
      }
    } else {
      if (np->curr_time.dns == 0)
        np->curr_time.dns = np->prev_time.dns ? np->prev_time.dns :
u_time;
      else if (u_time < np->curr_time.dns)
        np->curr_time.dns = u_time;
      if (np->status.err_bad_exist) {
        np->status.err_bad_repeat = 1;
        np->to_report = 1;
      }
    }
    np->status.err_bad_exist = 1;
    np->to_report = 1;
    DEBUG(0, (“cert curr_time %d %d\n”, np->curr_time.dns,
np->end_time.dns));
    return 1;
  } else {
    if (u_time > np->latest_time) {
      if (np->status.err_bad_exist) {
        np->status.err_bad_corrected = 1;
        /* np->curr_time.hs = 0; */
      }
      if (prev_err->err_bad_exist) {
        if (!np->status.err_bad_exist)
          np->curr_time.dns = 0;
        if (!np->status.err_bad_corrected)
          np->end_time.dns = u_time;
        np->status.err_bad_prev_corrected = 1;
        np->to_report = 1;
        DEBUG(0, (“cert curr_time %d %d\n”, np->curr_time.dns,
np->end_time.dns)
);
        return 0;
      }
    } else {
      if (prev_err->err_bad_exist) {
        if (np->end_time.dns) {
          if (u_time < np->end_time.dns) {
            np->end_time.dns = u_time;
            np->to_report = 1;
          }
        } else {
          np->end_time.dns = u_time;
          np->to_report = 1;
        }
      }
    }
    DEBUG(0, (“cert curr_time %d %d\n”, np->curr_time.dns,
np->end_time.dns));
    return 0;
  }
}
```

1. A system for maintaining and reporting an error state corresponding to agent testing of a computer network, comprising;
one or more agents to execute a test of the computer network;
an error data structure associated with each agent for storing an error state associated with the test performed by the agent associated with the error data structure;
an initiator to initiate the test;
an evaluation engine to evaluate result messages returned by the one or more agents after the one or more agents execute the test in the context of the error data structure associated with each agent, wherein the evaluation engine waits until expiration of a dampening window prior to evaluating the result messages and updates the error data structure associated with each agent in accordance with the result messages returned by the one or more agents;
a database for storing the current state; and
a notification system to notify a user of a detected error, wherein the system executes follow-up testing upon detection of certain events.
